(19) United States
(12) Patent Application Publication
(10) Pub. No.: US 2026/0220316 A1
(43) Pub. Date: Jul. 30, 2026

(54) METHODS AND SYSTEMS OF ENHANCING EDGE PLACEMENT ERROR INSPECTION

(71) Applicant: Applied Materials Israel Ltd., Rehovot (IL)

(72) Inventor: Shay ATTAL, Rehovot (IL)

(21) Appl. No.: 19/039,658

(22) Filed: Jan. 28, 2025

(51) Int. Cl. G06F 30/12

(52) U.S. Cl. CPC G06F 30/12

(57) ABSTRACT

This disclosed subject matter includes a computer-implemented method and computer system for enhancing and/or optimizing metrology recipes for Edge Placement Error (EPE) measurements, including roughness, Critical Dimensions (CD), and Critical Dimension Uniformity (CDU). The approach uses skewed CAD versions and a CAD-to-SEM ML model to generate synthetic SEM images for recipe validation. An iterative process refines recipes by adjusting recipe parameters based on discrepancies between measured values and true values.

### FIELD OF THE INVENTION

The present invention relates generally to semiconductor manufacturing and, more particularly, to systems and methods for edge placement error inspection and control in semiconductor device manufacturing processes.

### BACKGROUND OF THE INVENTION

Edge Placement Error (EPE) is an important metric in semiconductor manufacturing that measures feature edge deviation from intended design positions. EPE encompasses various metrics including overlay misalignments, line edge roughness (LER), critical dimension (CD), and critical dimension uniformity (CDU). Managing these factors is essential for maintaining accuracy in miniaturized device structures.

For example, overlay, measuring alignment between successive device layers, is a key EPE component. Modern inspection systems use scatterometry, electron microscopy, and optical diffraction to analyze dedicated targets like box-in-box or bar-in-bar patterns. These systems precisely measure X-Y positional deviations to ensure accurate layer-to-layer alignment.

### GENERAL DESCRIPTION

According to a first aspect of the presently disclosed subject matter, there is provided a computer-implemented method of validation and/or enhancing Edge Placement Errors (EPE) inspection recipes used for guiding a metrology tool during a measurement task of a semiconductor specimen, the method comprising (utilizing a processing circuitry for):
generating one or more skewed Computer-Aided Design (CAD) versions of a semiconductor specimen, wherein each skewed CAD version exhibits a deviation or distortion when compared to an optimal reference design;
applying the one or more skewed CAD versions and physical model outputs to a machine learning (ML) model trained to generate synthetic skewed SEM (Scanning Electron Microscope) images; wherein the ML model is trained using CAD data and real SEM images, along with physical model outputs of a (matching) physical model, to generate synthetic SEM images that emulate variations reflecting the respective physical model, and wherein the physical model is indicative of structural and material parameters, and tool setting parameters of an SEM tool used for generating the real SEM images;
obtaining from the ML model at least one synthetic SEM image of the semiconductor specimen; applying a metrology tool on the at least one synthetic SEM image, wherein the metrology tool is applied using an EPE inspection recipe for guiding the metrology tool during measurements of parameters in the semiconductor specimen or part thereof; comparing true parameter values with measured parameters values determined by the metrology tool; and validating the EPE inspection recipe if a difference between the true parameters values and measured parameters values are within an acceptable range.

In addition to the above features, the method according to this aspect of the presently disclosed subject matter can optionally comprise one or more of features (i) to (viii) below, in any technically possible and technically possible combination or permutation:
i. Wherein in case a difference between the true parameters values and measured parameters values deviates from the acceptable range, the method comprising performing a recipe optimization procedure:
   modifying parameters in the recipe to obtain an updated recipe;
   re-applying the metrology tool on the at least one synthetic SEM image using the updated recipe;
   comparing between true parameter values with measured parameter values determined by the metrology tool;
   validating the recipe if one or more differences between the true parameter values and measured parameter values are within an acceptable range; and repeating the recipe optimization procedure if one or more differences deviate from the acceptable range.
ii. Wherein the physical model output includes one or more of: simulated SEM images; signal intensity maps; and electron scattering profiles.
iii. Wherein the one or more skewed CAD versions include multiple distinct CAD versions, with each distinct CAD version exhibiting a different deviation or distortion.
iv. Wherein the EPE is overlay misalignment, and wherein the deviations or distortions include misalignment between different layers of the semiconductor specimen.
v. Wherein the EPE is line edge roughness, and wherein the deviations or distortions include variations in the edge geometry or surface irregularities of the semiconductor specimen.
vi. Wherein the EPE is one of (i) Critical Dimension (CD) deviation, wherein the deviations or distortions include variations in the size of features within a single layer of the semiconductor specimen, or (ii) Critical Dimension Uniformity (CDU) error, wherein the deviations or distortions include inconsistencies in feature sizes across different regions of the semiconductor specimen.
vii. The method further comprises training the machine learning model using a training data set comprising CAD data of a semiconductor specimen, along with corresponding real SEM images and outputs generated by a matching physical model of the semiconductor specimen.
viii. Wherein generating the one or more skewed CAD versions comprises generating multiple skewed CAD versions, each corresponding to a unique type or degree of EPE variation;
   the machine learning (ML) model is utilized to generate a respective synthetic skewed SEM image for each skewed CAD design version, wherein the synthetic skewed SEM images reflect EPE variations exhibited in a respective skewed CAD version;
   the metrology tool is applied to each synthetic SEM image using the given EPE inspection recipe to thereby perform evaluation of the recipe across a variety of scenarios represented by the respective skewed CAD versions to assess robustness and sensitivity to different EPE variations.

According to a second aspect of the presently disclosed subject matter there is provided a computer system comprising a processing circuitry configured to execute the method of the first aspect above.

According to a third aspect of the presently disclosed subject matter there is provided a non-transitory computer-readable medium comprising instructions that, when executed by a computer, cause the computer to perform a method according to the first aspect above.

According to a fourth aspect of the presently disclosed subject matter there is provided a computer program product comprising a non-transitory computer-readable medium having computer-executable instructions stored thereon, which, when executed by a processor, cause the processor to execute a method according to the first aspect above.

The methods, the systems, and the non-transitory program storage devices, disclosed with reference to the second, third, and fourth aspects, can optionally comprise one or more of features (i) to (viii) listed above, mutatis mutandis, in any technically possible combination or permutation.

The presently disclosed subject matter further contemplates a semiconductor metrology tool comprising a processing circuitry configured to execute a method of validating and optimizing an EPE recipe for guiding the metrology tool during a measurement task and/or a semiconductor inspection process dedicated as disclosed herein.

The disclosed subject matter also includes a computer-implemented method of an EPE inspection process that includes optimization of an EPE inspection recipe as disclosed herein, a computer system for executing the method, and a non-transitory computer-readable medium with instructions that, when executed, cause a processor to perform the method.

### BRIEF DESCRIPTION OF THE DRAWINGS

In order to understand the presently disclosed subject matter and to see how it may be carried out in practice, the subject matter will now be described, by way of non-limiting examples only, with reference to the accompanying drawings, in which:

FIG. 1A shows a block diagram schematically illustrating an EPE inspection system, in accordance with certain examples of the presently disclosed subject matter;

FIG. 1B shows a block diagram schematically illustrating a computer system with EPE inspection recipe validation capabilities, in accordance with certain examples of the presently disclosed subject matter;

FIG. 2 is a flowchart of operations carried out as part of training and execution of a CAD-TO-SEM machine learning model, in accordance with certain examples of the presently disclosed subject matter; and

FIG. 3 is a flowchart of operations carried out during an EPE inspection recipe validation process, in accordance with certain examples of the presently disclosed subject matter.

### DETAILED DESCRIPTION

A metrology tool recipe is a predefined set of instructions, parameters, and algorithms that guide the tool in measuring semiconductor samples. It defines how to analyze data, process measurements, and deliver results with consistency, accuracy, and repeatability. Recipes evaluate key aspects like overlay, line edge roughness (LER), critical dimensions (CD), and critical dimension uniformity (CDU). Algorithms within the recipe support tasks such as data analysis, signal processing, edge detection, image processing, defect detection, statistical analysis, and calibration, enabling precise, automated, and efficient measurements.

For overlay metrology, recipes enable precise layer alignment analysis in multilayer specimens, guiding tools like scanning electron microscopes (SEM) to detect overlay errors accurately. For LER, recipes specify edge regions for analysis, resolution optimized for edge detection, and algorithms for quantifying roughness deviations, such as power spectral density (PSD) analysis and root mean square (RMS) roughness, ensuring precise monitoring of edge irregularities. For CD, recipes define sampling locations and feature types (e.g., trenches, lines) to measure individual feature dimensions. These recipes help detect problems such as feature size variations (e.g., inconsistent size of line features in different regions of the wafer) and patterning defects that directly affect the accuracy of the design. For CDU, recipes focus on evaluating dimensional consistency within a die, across wafers, and between wafers. These recipes are used to identify issues like intra-layer inconsistencies, systematic deviations, and random variations in feature sizes that can compromise overall process stability and device performance.

By standardizing these measurement processes, inspection recipes enable high-throughput, reliable data collection, and support process optimization in advanced semiconductor manufacturing.

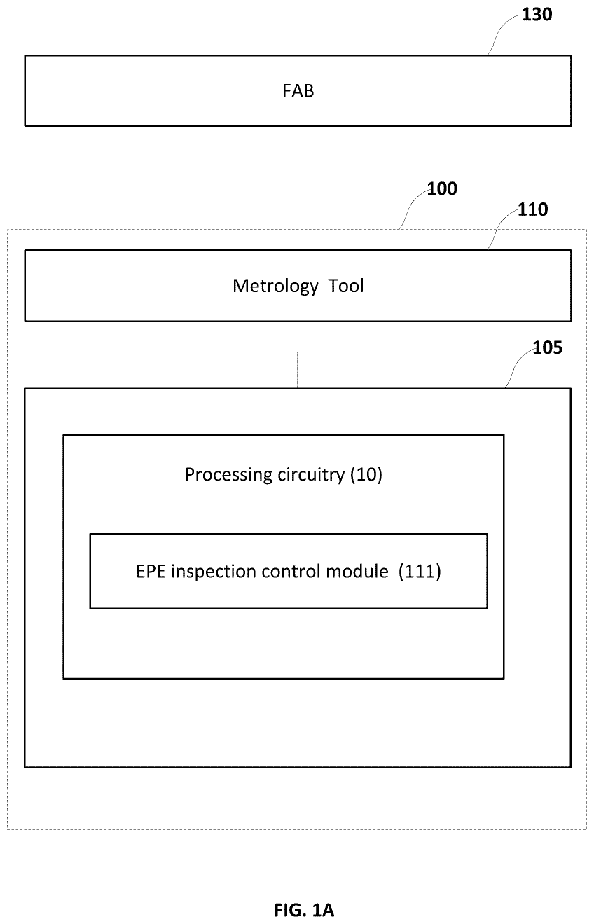

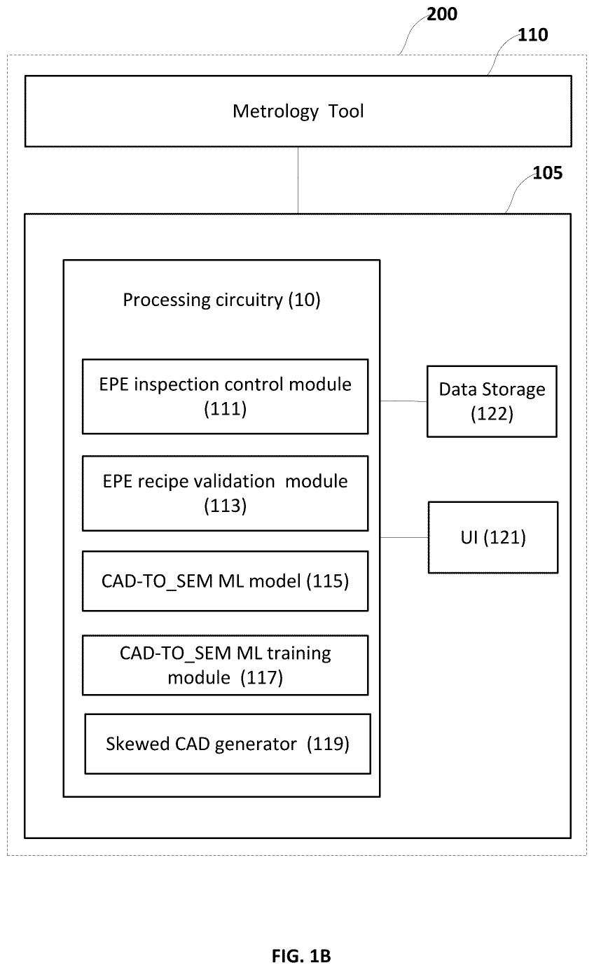

FIG. 1A illustrates a simplified schematic representation of an example of an EPE measurement system 100. The system includes a metrology tool 110 operatively connected to a semiconductor fabrication facility (FAB 130). The connection between the FAB and the metrology tool can be established through inline integration, where the tool is directly connected to the production line for real-time wafer inspection, offline metrology, where wafers are transported to a separate station for batch analysis, and through a hybrid setup combining buffer stations and automated transfers to enhance flexibility while ensuring timely feedback.

Metrology Tool 110 is a type of semiconductor examination tool used to measure and analyze the physical and structural properties of semiconductor wafers, such as dimensions, thickness, composition, and defects, ensuring precision and quality in the manufacturing process. Examination tools in general include inspection, review, and metrology functions, each serving distinct but complementary roles. Inspection rapidly scans the entire wafer to identify potential defects or anomalies, prioritizing speed and broad coverage. Review focuses on detailed analysis of flagged areas, providing precise characterization of defects.

Tools like Scanning Electron Microscopes (SEM) can perform both inspection and review tasks, operating in different modes to provide low-resolution imaging for rapid defect detection and high-resolution imaging for detailed analysis. SEMs also function as metrology tools, delivering high-resolution imaging and precise measurements to support both inspection and review processes. These functions can be performed by separate tools or integrated into a single tool with configurable settings.

An SEM works by directing a focused beam of high-energy electrons toward the sample surface, generated by an electron gun and controlled using electromagnetic lenses. As the beam interacts with the sample, it produces signals like secondary electrons, backscattered electrons, and characteristic X-rays. The detection of secondary electrons, emitted from atoms near the surface, enables an SEM to produce high-resolution grayscale images that reveal surface topography. Similarly, backscattered electrons, deflected by the atomic nuclei in the sample, provide compositional contrast based on atomic number differences. These signals are captured by detectors and processed into images that reflect the sample's surface structure, composition, and other properties. Such images are essential for assessing surface conditions, identifying defects, and providing data for subsequent analysis.

Semiconductor specimens (e.g., wafers, dies, or parts thereof) are examined by the metrology tool using a predefined recipe applied during the examination. A computer system 105, operatively connected to the metrology tool (or integrated within it), includes an overlay EPE inspection control module 111 configured to control the EPE measurement process. This module applies the operational parameters defined in the recipe to the metrology tool during examination of the specimen. Additionally, the computer system can receive measurement data from the metrology tool and validate the compliance of the specimens with the desired specifications.

However, when a recipe is inadequately defined or improperly calibrated, it can produce inaccurate EPE measurements. Improperly configured recipes may fail to account for variations in materials, process conditions, or target geometries, resulting in measurement errors that compromise alignment precision, reduce device performance, and ultimately lower production yields. For example, a poorly designed overlay recipe may lead to misalignment issues that propagate through subsequent manufacturing stages.

One problem related to faulty recipes is their potential to produce errors that remain undetected during the initial stages. Inaccurate measurement results may not immediately signal issues with the recipe, allowing deviations to go unnoticed until subsequent processing steps reveal the underlying problem. Once identified, the manufacturing process often must be interrupted to refine or develop a new recipe, causing production delays. This interruption can incur significant costs in the form of downtime, wasted wafers, and rework.

Therefore, developing robust and adaptable recipes is essential to ensure accurate and reliable EPE measurements. Such recipes minimize the risk of disruptions, support efficient production, and maintain the high standards of semiconductor manufacturing.

The presently disclosed subject matter includes a computer-implemented method and a computer system for evaluating and enhancing EPE measurements to achieve robust EPE control. By identifying and correcting recipe-induced errors early in the process, the disclosed method helps to minimize disruptions, ensure high-yield production, and preserve the integrity of the semiconductor manufacturing process.

The system utilizes synthetic SEM images of the semiconductor specimen, generated through a machine learning model trained to create these images while accounting for EPEs. For EPEs involving interlayer relationships, such as overlay, the model considers the alignment between different layers. In cases like Critical Dimension (CD) errors, the model focuses on feature variations within individual layers. This approach ensures accurate representation of EPEs across various dimensions and layers of the specimen.

To this end, a machine learning model is trained to generate synthetic SEM images from CAD (Computer-Aided Design) data, enabling the simulation of real SEM images without the need for actual scans. These models are trained to correlate CAD data (representing an ideal design) with SEM images (reflecting real-world, post-fabrication structures). While CAD represents the desired theoretical model, real fabrication often introduces deviations from this ideal, such as variations in line width or surface imperfections. The machine learning model, trained on actual SEM images, learns how these deviations manifest in the final output. Given a certain CAD design, the model can simulate the predicted deviations in the examination output, providing a more accurate representation of how the fabricated structure will appear.

While using machine learning models to generate synthetic SEM images offers various benefits, achieving accurate results depends on multiple interconnected factors, including stack information (including for example layer composition, thickness, and material properties), pattern design (such as overlay targets or feature geometries), machine configurations, and scanning parameters, which have a direct affect on how the SEM signal is generated. For example, SEM machine configurations (such as beam voltage, aperture size, working distance, and magnification) affect the interaction of the electron beam with the specimen, altering the image quality and resolution. Failure to account for these parameters during the model's training and execution can lead to synthetic SEM images that deviate from the real-world outputs the model is designed to simulate, reducing their reliability and applicability in practical use cases.

To address this challenge, the presently disclosed subject matter includes a tool-specific machine learning model trained to receive input data comprising CAD data and outputs of a matching physical model. The physical model incorporates the factors mentioned above by mathematically representing the stack information, pattern geometries, and material properties alongside the SEM machine settings parameters. This integration allows the model to simulate the interactions between the electron beam and the specimen, accurately predicting signal behavior, image formation, and variations based on real-world conditions. The stochastic nature of electron scattering is modeled (using for example Monte Carlo methods), providing detailed simulations of electron trajectories, backscattering events, and secondary electron generation. The physical model outputs include simulated SEM images, signal intensity maps, and electron scattering profiles, offering predictions of how the electron beam interacts with the specimen under various conditions.

By integrating part or all of physical model outputs of a matching model into the machine learning model, the disclosed system ensures that the synthetic SEM images more closely mirror the real examination outputs, thereby enhancing the accuracy and reliability of the simulations. This approach allows for precise adjustments of the model according to real-world conditions, thus improving fidelity of the synthetic images. Consequently, this enables to apply more accurate and effective methods for enhancing metrology recipes.

Attention is now drawn to FIG. 1B, which is a schematic block-diagram of a computer system 200 that includes EPE inspection recipes validation and enhancement capabilities, in accordance with some examples of the presently disclosed subject matter. The system leverages machine learning (ML) models to enhance the robustness of EPE validation and the analysis of factors such as overlay, LER, CD, and CDU, to ensure precise feature placement during semiconductor manufacturing. System 200 includes some elements that overlap with those shown as part of System 100 in FIG. 1A. These overlapping elements may share similar functionality or components, highlighting areas where the systems integrate or complement each other.

By way of example, processing circuitry 12 is shown to comprise various functional modules that facilitate operations related to the validation and optimization of EPE recipes, ensuring robust process control. Processing circuitry 12 can comprise one or more processors and one or more memories (not shown). In some examples, the processing circuitry is configured to execute the functional modules based on computer-readable instructions stored in a non-transitory computer-readable memory included in the processing circuitry. These functional modules are hereinafter referred to as being comprised in the processing circuitry.

Per the illustrated example, the functional modules include an EPE inspection control module 111 configured to oversee the EPE measurement process as mentioned above; an EPE recipe validation module 113 configured to validate an EPE inspection recipe, a CAD-TO-SEM machine learning (ML) model 115 trained to generate synthetic SEM images based on CAD data, a CAD-TO-SEM training module 117 configured to execute the training of the CAD-TO-SEM ML model to obtain the trained model, and a skewed CAD generator 119 configured to generate the skewed CADs.

The division into the particular modules as illustrated in FIG. 1B is provided solely by way of example to aid in understanding the functions of system 200. This division is strictly illustrative and should not be construed as limiting, as other configurations or implementations may be used instead. Notably, while FIG. 1B depicts CAD-TO-SEM 115 and the training module 117 as integrated components of system 200, this integration is not mandatory in all implementations. In some cases, system 200 may not perform the training process directly. Instead, the training can be conducted externally, with system 200 receiving the pre-trained model from an independent environment. Additionally, execution of the model may also occur externally, with the synthetic images generated by the model being provided to system 200 for use during EPE inspection recipe validation and optimization.

According to some examples, system 200 can comprise or be otherwise operatively connected to a data-storage unit 122 configured to store any data necessary for operating system 200. This includes for example computer software which is loaded during execution of any one of the modules described above, intermediate processing results generated by system 200, physical model outputs, synthetic SEM output images, etc.

In some examples, system 200 can optionally comprise a user interface 121 to enable user interaction with system 200. The user interface can include a display device, user interaction devices (e.g., computer mouse and keyboard) and a graphical user interface (GUI) configured to enable, inter alia, user-specified inputs related to system 100. For instance, the user may view on the display the processing results or intermediate processing results, such as, e.g., synthetic SEM images, outputs of the EPE configuration module 113, etc.

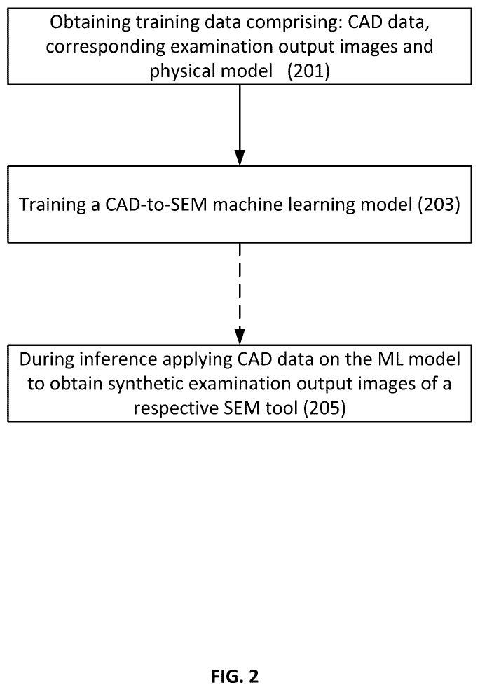

Attention is now reverted to FIG. 2 showing a flowchart of operations carried out during training of a CAD-TO-SEM machine learning model, according to some examples of the presently disclosed subject matter.

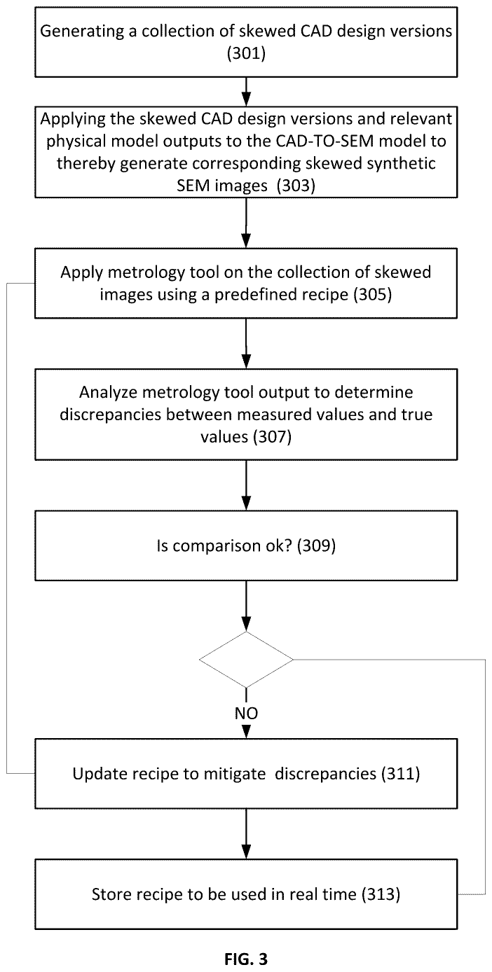

It is noted that while operations in FIGS. 2 and 3 are described with reference to various components in FIG. 1B, this is done by way of example only and should not be construed as limiting the processes to the specific system design illustrated in any of these figures.

A training dataset comprising data for training the CAD-to-SEM ML model is obtained (block 201). The training dataset includes CAD designs of a semiconductor specimen, along with their corresponding SEM images (referred to as “real SEM images”) and the outputs generated by a physical model that simulates the behavior of the semiconductor specimen during scanning. This physical model is referred to herein as the matching physical model. The purpose of this training is to develop a machine learning model that takes CAD data and physical model outputs as inputs, and generates corresponding synthetic SEM images that accurately reflect variations based on the physical model outputs.

As mentioned above, the physical model represents the operational setup, encompassing specimen characteristics and operational parameters applied during the SEM imaging process. This setup includes SEM tool settings, structural and material properties of the specimen, and possibly also environmental conditions, and other factors that collectively determine how the electron beam interacts with the specimen. By accurately modeling these parameters, the physical model outputs provide a detailed understanding of electron beam interactions and their effects on SEM imaging and analysis.

These outputs include simulated SEM images, signal intensity maps, and electron scattering profiles. Simulated SEM images replicate the output of a real SEM, offering high-resolution visual representations influenced by material composition, stack information (describing the layered architecture, including material composition and dimensions), pattern geometries, and SEM tool settings. Key settings, such as beam voltage, aperture size, working distance, and magnification, affect resolution, depth of field, and contrast.

Signal intensity maps illustrate the spatial distribution of emitted signals, such as secondary and backscattered electrons, revealing material contrasts, surface topography, and feature boundaries. Electron scattering profiles describe the interaction of electrons with the specimen, capturing scattering angles, trajectories, and energy distributions. A typical visualization derived from these profiles is a graph plotting backscattered electron (BSE) yield versus distance, showing how BSE yield varies across the sample surface or relative to a reference point.

Predefined data elements selected from the above physical model outputs can be added to the training dataset. The physical model output is derived from the operational setup and other parameters defined in the physical model, providing data to train machine learning models to predict how variations in these parameters influence SEM images. The training dataset can be stored and made available for training in a computer data-storage operatively connected to system 200, e.g., storage unit 122.

At block 203, the training dataset is used to train the machine learning model. This dataset includes CAD files, real SEM images, and physical model output data, enabling the CAD-to-SEM model to learn the relationship between specific physical model output parameters and observed variations in SEM images. The ground truth, consisting of actual SEM images generated by the SEM tool, serves as a reference during training. The model is optimized by minimizing the difference between synthetic SEM images and the ground truth, allowing it to generate accurate and realistic synthetic SEM images under various conditions defined by different physical model parameters. Training can be executed using the CAD-to-SEM training module 117.

Block 205 refers to the inference stage, where the CAD-to-SEM model (115) generates synthetic SEM images. The model is provided with new CAD data and corresponding physical model outputs. By applying physical model outputs that match the properties of a specific operational setup, the model produces synthetic SEM images that closely resemble real SEM images generated under similar conditions.

In some examples, CAD-to-SEM model (115) is implemented as a deep neural network (DNN). DNN can refer to a supervised or unsupervised DNN model which includes layers organized in accordance with respective DNN architecture. By way of non-limiting example, the layers of DNN can be organized in accordance with Convolutional Neural Network (CNN) architecture, Recurrent Neural Network architecture, Recursive Neural Networks architecture, Generative Adversarial Network (GAN) architecture, or otherwise. Each layer of DNN can include multiple basic computational elements (CE), typically referred to in the art as dimensions, neurons, or nodes.

Once the CAD-to-SEM ML model is available, it can be used for generating synthetic SEM output images that can be used in a variety of applications, including improving the accuracy and efficiency of SEM image analysis.

Attention is now reverted to FIG. 3, which illustrates a flowchart of operations carried out during an EPE inspection recipe configuration process, according to some examples of the presently disclosed subject matter.

The process described with reference to FIG. 3 outlines operations which can be applied to different types of Edge Placement Errors (EPEs). The inclusive framework described in FIG. 3 enables its application to various EPEs, such as overlay, roughness, Critical Dimension (CD), and Critical Dimension Uniformity (CDU). The following explanation demonstrates how these operations can be specifically applied to overlay and roughness inspections.

For overlay, the process begins by generating skewed CAD versions (301). In some examples, the skewed CAD versions are generated for a particular target in the semiconductor specimen. A target can include, for example, a particular region within the specimen (e.g., wafer) such as a test structure or a portion of a device. In general, a skewed CAD version represents a design that includes intentional deviations or distortions in its patterns, reflecting undesirable variations when compared to an optimal reference design. In case of overlay, the skewed CAD versions include designs that mimic the appearance of a specimen with overlay misalignment, providing a basis for evaluating and optimizing overlay inspection recipes. The generation of the skewed CAD versions involves the intentional alteration of the original CAD design of the semiconductor specimen to reflect overlay misalignments, or deviations that may occur in real-world scenarios. These skewed CAD versions simulate non-ideal conditions, providing the model with a diverse range of overlay misalignment training data.

The true dimensions and overlay misalignments observed in the skewed CAD versions are recorded and stored for later use. This stored data serves as a reference for comparing the measurements obtained during overlay inspection, enabling an accurate evaluation of the measurement recipe's performance and its ability to detect and quantify deviations effectively.

The CAD design represents the multilayer structure of a semiconductor specimen, with each layer in the CAD corresponding to a different physical layer of the device. For example, one layer in the CAD may include line patterns, while another layer includes contact hole patterns. The alignment between these layers can be intentionally degraded in the CAD design by altering the position of the lines in one layer relative to the holes in another layer. In some examples, multiple skewed CAD versions are generated for a given specimen, with each version applying a different type or degree of misalignment. This approach introduces variety among the skewed CAD designs, allowing for comprehensive testing and validation of metrology tools.

The generation of skewed CAD versions can be carried out by the skewed CAD generator 119. In some implementations, the skewed CAD generator 119 is a computer program that incorporates a user interface (e.g., UI 121) and a CAD engine. The user interface provides tools that allow users to specify the type and degree of modifications, such as introducing misalignments, distortions, or edge roughness. The CAD engine processes these specifications and applies the desired alterations to the original CAD designs, generating skewed versions. This combination of user control and automated processing ensures precision and flexibility in creating modified CAD versions for testing and analysis. In other examples, the entire process can be automated, with predefined parameters and algorithms within the CAD engine generating skewed versions without user intervention. This fully automated approach allows for high-throughput creation of modified designs, suitable for scenarios where large-scale testing or consistent variation patterns are required.

At block 303 the CAD-TO-SEM ML (115) model described above is used to generate a collection of synthetic skewed SEM images of a specific semiconductor specimen (or a particular target within the specimen) generated under specific conditions. For the selected target in a semiconductor specimen, the skewed CAD versions, along with the corresponding physical model outputs generated by the matching physical model, are applied to the ML model as input. The CAD-TO-SEM ML model generates corresponding synthetic skewed SEM images that exhibit misalignments.

At block 305, the metrology tool is applied to the collection of synthetic skewed SEM images. The metrology tool measures the overlay between different layers in the specimen, as they appear in the synthetic images. Instead of applying the tool to the specimen itself or to real SEM images generated by scanning the specimen, it is applied to synthetic images artificially generated for evaluating the recipe. This approach enables testing and refining the metrology recipe under controlled conditions, ensuring it performs accurately across a range of simulated scenarios before being applied to real-world samples.

The overlay inspection is performed with the metrology tool configured according to a specific inspection recipe. As explained above, the recipe defines the tool's operating parameters intended to effectively apply the overlay inspection. However, poorly configured recipes can result in inaccurate overlay measurements, leading to unreliable inspection results.

The collection of synthetic skewed SEM images enables the metrology tool to measure a variety of deviations and misalignments. By simulating different degrees and types of distortions in the synthetic images, the tool can assess how well it detects and quantifies overlay errors under diverse conditions.

Various overlay alignment parameters can be measured in an overlay inspection process, including for example:
Overlay Error (Overlay Offset): The misalignment between layers, typically measured in the x and y directions.
Alignment Target Position: The precise location of overlay targets, such as box-in-box or frame-in-frame structures, used to evaluate layer-to-layer alignment accuracy.
Displacement Metrics (Pattern Shift): The relative lateral shift of features between layers. For example, the relative position of lines in one layer and contact holes in another.
Rotational Errors: Angular misalignment between layers, which affects the overall overlay precision.

In some examples, the EPE recipe is provided to EPE inspection control module 111 (e.g., retrieved from storage unit 122) together with the synthetic skewed SEM images, which are configured to use the metrology tool 110 for applying metrology measurements on the images.

At block 307, the output of the metrology tool is analyzed to identify discrepancies between the measured overlay alignment parameters and the reference (true) values recorded earlier in the process. This analysis serves to detect deviations or errors in the overlay measurements, which may result from recipe misconfiguration.

At decision block 309, it is determined whether the discrepancies are within acceptable limits. In some examples, the results are presented to an operator, indicating whether the recipe is satisfactory or requires further adjustment. Additionally, a visual or audible alert may be generated to notify the operator of the outcome. If the results show that the difference between the measured and true values is zero or within an acceptable range, the recipe is validated; otherwise, it is rejected.

In some examples, the process can stop at this point following validation or rejection of the recipe. In other examples, the process continues to execute an automatic recipe optimization procedure, as further explained below.

If the comparison between the measured overlay alignment parameters and the reference (true) values is not satisfactory, the process proceeds to block 311, where the overlay inspection recipe is updated to address the identified discrepancies. This step may involve modifying tool settings, algorithm-related parameters, or both, to enhance the accuracy of the overlay measurements and improve performance in subsequent iterations.

Modifiable tool settings may include parameters such as accelerating voltage, beam current, working distance, focus, and illumination mode. Algorithm-related modifications may involve adjustments to parameters that control image processing, measurement logic, and sensitivity settings. These changes affect how algorithms process images, detect features, and measure overlay alignment, ultimately optimizing the system's accuracy, precision, and sensitivity.

The process is iterative, and, after each update, the procedure repeats using the updated recipe. The updated recipe is applied during subsequent overlay inspections, including on synthetic images, for further evaluation. In some examples, the process continues until a stopping criterion is met—for instance, when the comparison at block 307 yields satisfactory results, indicating that the recipe has been successfully optimized to provide accurate and reliable overlay measurements in practical applications. At block 313, the optimized recipe is finalized and stored, ensuring its availability for real-time application in semiconductor manufacturing processes.

In some examples, outputs of the metrology tool are provided to EPE recipe validation module 113 which executes the operations described with reference to blocks 307 to 311. Once a validated recipe is obtained, it is sent to EPE inspection control module 111 to be used in a subsequent EPE inspection.

A similar process to that described above can be applied for validating and optimizing recipes dedicated to other Edge Placement Error (EPE) measurements. The underlying principles of discrepancy analysis and recipe refinement can be adapted and modified to accommodate the specific requirements of different types of inspections, ensuring precision and efficiency across various metrology applications.

A process following the same principles can be applied for validating and optimizing roughness inspection recipes. At block 301, skewed CAD versions of a semiconductor specimen target are generated. These skewed CAD versions are created to mimic the appearance of a specimen with varying degrees of roughness, such as line edge roughness (LER) for lines and general edge roughness for other patterns. The generation of the skewed CAD versions involves intentional modifications to the original CAD design to reflect different levels of roughness, providing a basis for evaluating and optimizing EPE inspection recipes. To introduce line roughness variations in a semiconductor CAD design, mathematical models such as Gaussian noise, Perlin noise, or Fourier-based functions are applied to generate irregularities along the edges of lines or patterns. These variations can be tailored to simulate real-world manufacturing imperfections, reflecting specific spatial frequencies or statistical distributions.

At block 303, the CAD-to-SEM ML model is used to generate a collection of synthetic skewed SEM images based on the skewed CADs and corresponding physical model outputs. As explained earlier, the collection of synthetic skewed SEM images with varying roughness enables the metrology tool to evaluate a range of edge irregularities. By simulating diverse degrees and types of distortions, the tool's ability to detect and quantify roughness variations under different conditions can be thoroughly assessed.

At block 305, the metrology tool is applied to the collection of synthetic skewed SEM images. The metrology tool measures the roughness of the patterns in the specimen, where each synthetic image corresponds to a respective pattern. Roughness measurements can be characterized by the standard deviation (STD) of the critical dimension (CD) along the pattern or using power spectral density (PSD) techniques.

At block 307, the output of the metrology tool is analyzed to determine discrepancies between the measured roughness values and the true values recorded earlier in the process. At decision block 309, a comparison is made to check if the discrepancies are within acceptable limits.

If the comparison is not satisfactory, the process proceeds to block 311, where the roughness inspection recipe is updated to address the identified discrepancies. This involves adjusting the tool settings or algorithm-related parameters to improve measurement accuracy. The updated recipe is then used in subsequent iterations of the process. The process continues iteratively until the comparison at block 309 yields satisfactory results, at which point the optimized recipe is finalized for real-time use in semiconductor manufacturing processes.

The process iterates with each update, using the revised recipe for roughness inspections on synthetic images. This continues until block 309 yields satisfactory results, signifying an optimized recipe ready for real-time use in semiconductor manufacturing.

The process described in FIG. 3 can be applied to other types of Edge Placement Errors (EPEs), as needed. For Critical Dimensions (CD), skewed CAD versions may include variations in feature sizes, such as line widths or trench widths. The CAD-to-SEM model generates synthetic SEM images reflecting these variations, and the metrology tool measures the CD values in the synthetic images. The recipe is iteratively refined to ensure accurate CD measurements.

Similarly, for Critical Dimension Uniformity (CDU), skewed CAD versions may represent feature uniformity variations across different wafer regions. The CAD-to-SEM model generates synthetic SEM images showing these variations, and the metrology tool measures CDU values. The recipe is iteratively refined to ensure accurate CDU measurements across the wafer. By applying this process to various types of EPEs, the system supports comprehensive validation and optimization of metrology recipes, enhancing the accuracy and reliability of semiconductor manufacturing processes.

Those versed in the art will readily appreciate that the teachings of the presently disclosed subject matter are not bound by the system illustrated in FIGS. 1A and 1B. Each system component and module in FIGS. 1A and 1B can be made up of any combination of software, hardware, and/or firmware, as relevant, executed on a suitable device or devices, which perform the functions as defined and explained herein. Equivalent and/or modified functionality, as described with respect to each system component and module, can be consolidated or divided in another manner. Thus, in some embodiments of the presently disclosed subject matter, the system may include fewer, more, modified, and/or different components, modules, and functions than those shown in FIGS. 1A and 1B.

Each component in FIGS. 1A and 1B may represent one or more instances of the same component. These instances may operate independently or cooperatively to process various data and electrical inputs and enable operations associated with a computerized examination system. Multiple instances of a component may be employed for purposes such as improving performance, ensuring redundancy, enhancing availability, or supporting specific functionality. For example, certain portions of a component's functionality may be allocated across different instances of the component.

While certain examples of the present disclosure refer to a processing circuitry being configured to perform the above-recited operations, the functionalities/operations of the aforementioned functional modules can be performed by the one or more processors in the processing circuitry in various ways. By way of example, the operations of each module can be performed by a specific processor, or by a combination of processors. The operations of the various functional modules, such as processing the examination/inspection image, and performing defect examination, etc., can thus be performed by respective processors (or processor combinations), while, optionally, these operations may be performed by the same processor. The present disclosure should not be limited to being construed as one single processor always performing all the operations. The present disclosure should not be construed as limiting the described operations to being performed exclusively by a single processing circuitry. Furthermore, any reference made in the specification and claims to a single processing circuitry should be interpreted to optionally include multiple processing circuitries. These multiple processing circuitries may operate independently or collaboratively, with interoperability enabling communication, data exchange, and task sharing to achieve the described functionalities.

The systems illustrated in FIGS. 1A and 1B can be implemented in a distributed computing environment, in which one or more of the aforementioned components and functional modules shown in FIGS. 1A and 1B can be distributed over several local and/or remote devices. By way of example, training module 117 can be located at the same entity (in some cases hosted by the same device) or on a different device located at a different location.

In some examples, certain components utilize a cloud implementation, e.g., are implemented in a private or public cloud. Communication between the various components of the examination system, in cases where they are not located entirely in one location or in one physical entity, can be realized by any signaling system or communication components, modules, protocols, software languages, and drive signals, and can be wired and/or wireless, as appropriate.

Unless specifically stated otherwise, as apparent from the above discussions, it is appreciated that, throughout the specification, discussions utilizing terms such as “obtaining”, “generating”, “applying”, “comparing”, or the like, include an action and/or processes of a computer that manipulate and/or transform data into other data, said data represented as physical quantities, e.g. such as electronic quantities, and/or said data representing the physical objects.

The terms “computer” , “computer system”, “computer device”, “computerized device”, “computerized system” or the like used herein, should be expansively construed to include any kind of hardware-based electronic device with one or more data processing circuitries. Each processing circuitry can comprise, for example, one or more processors operatively connected to computer memory, capable of executing stored instructions to perform the operations described herein. Any reference made in the description or claims to a processing circuitry should be construed to include also multiple processing circuitries.

The one or more processors referred to herein can represent one or more general-purpose processing devices such as a microprocessor, a central processing unit, or the like. More particularly, a given processor may be one of a complex instruction set computing (CISC) microprocessor, a reduced instruction set computing (RISC) microprocessor, a very long instruction word (VLIW) microprocessor, a processor implementing other instruction sets, or a processor implementing a combination of instruction sets. The one or more processors may also be one or more special-purpose processing devices such as an application-specific integrated circuit (ASIC), a field programmable gate array (FPGA), a digital signal processor (DSP), a graphics processing unit (GPU), a network processor, or the like.

It is appreciated that certain features of the presently disclosed subject matter, which are, for clarity, described in the context of separate embodiments, may also be provided in combination in a single embodiment. Conversely, various features of the presently disclosed subject matter, which are, for brevity, described in the context of a single embodiment, may also be provided separately, or in any suitable sub-combination.

It will also be understood that the system according to the presently disclosed subject matter may be a suitably programmed computer. Likewise, the presently disclosed subject matter contemplates a computer program being readable by a computer for executing the method of the presently disclosed subject matter. The presently disclosed subject matter further contemplates a machine-readable (e.g., non-transitory) memory tangibly embodying a program of instructions executable by the machine for executing the method of the presently disclosed subject matter.

It is to be understood that the presently disclosed subject matter is not limited in its application to the details set forth in the description contained herein or illustrated in the drawings. The presently disclosed subject matter is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the present presently disclosed subject matter.

1. A computer-implemented method of enhancing Edge Placement Errors (EPE) inspection of a semiconductor specimen, the method comprising:
generating one or more skewed Computer-Aided Design (CAD) versions of a semiconductor specimen, wherein each skewed CAD version exhibits a deviation or distortion when compared to an optimal reference design;
applying the one or more skewed CAD versions and physical model outputs to a machine learning (ML) model trained to generate synthetic skewed SEM (Scanning Electron Microscope) images; wherein the ML model is trained using CAD data and real SEM images, along with physical model outputs of a matching physical model, to generate synthetic SEM images that emulate variations reflecting the respective physical model; wherein the matching physical model is indicative of structural and material parameters, and tool setting parameters of an SEM tool used for generating the real SEM images,
obtaining from the ML model at least one synthetic SEM image of the semiconductor specimen;
applying a metrology tool on the at least one synthetic SEM image to measure parameters in the semiconductor specimen or part thereof, wherein the metrology tool is applied using an EPE inspection recipe for guiding the metrology tool during measurements;
comparing true parameter values of the semiconductor specimen with measured parameter values determined by the metrology tool; and
validating the EPE inspection recipe if differences between the true parameter values and measured parameter values are within an acceptable range.

2. The method of claim 1, wherein in case a difference between the true parameter values and measured parameter values deviates from the acceptable range, the method comprises performing a recipe optimization procedure:
modifying parameters in the recipe to obtain an updated recipe;
re-applying the metrology tool on the at least one synthetic SEM image using the updated recipe;
comparing between true parameter values with measured parameter values determined by the metrology tool;
validating the recipe if one or more differences between the true parameter values and measured parameter values are within an acceptable range; and repeating the recipe optimization procedure if one or more differences deviate from the acceptable range.

3. The method of claim 1, wherein the physical model output includes one or more of: simulated SEM images; signal intensity maps;
and electron scattering profiles.

4. The method of claim 1, wherein the one or more skewed CAD versions include multiple distinct CAD versions, with each distinct CAD version exhibiting a different deviation or distortion.

5. The method of claim 1, wherein the EPE is overlay misalignment, and wherein the deviations or distortions include misalignment between different layers of the semiconductor specimen.

6. The method of claim 1, wherein the EPE is line edge roughness, and wherein the deviations or distortions include variations in the edge geometry or surface irregularities of the semiconductor specimen.

7. The method of claim 1, wherein the EPE is one of (i) Critical Dimension (CD) deviation, wherein the deviations or distortions include variations in the size of features within a single layer of the semiconductor specimen, or (ii) Critical Dimension Uniformity (CDU) error, wherein the deviations or distortions include inconsistencies in feature sizes across different regions of the semiconductor specimen.

8. The method of claim 1 further comprising training the machine learning model using a training data set comprising CAD data of a semiconductor specimen, along with corresponding real SEM images and outputs generated by a matching physical model of the semiconductor specimen.

9. The method of claim 1, wherein, generating the one or more skewed CAD versions comprises generating multiple skewed CAD versions, each corresponding to a unique type or degree of EPE variation;
the machine learning (ML) model is utilized to generate a respective synthetic skewed SEM image for each skewed CAD design version, wherein the synthetic skewed SEM images reflect EPE variations exhibited in a respective skewed CAD version;
the metrology tool is applied to each synthetic SEM image using the given EPE inspection recipe to thereby perform evaluation of the recipe across a variety of scenarios represented by the respective skewed CAD versions to assess robustness and sensitivity to different EPE variations.

10. A computer system configured for enhancing Edge Placement Errors (EPE) inspection of a semiconductor specimen, the computer system comprising a processing circuitry configured to:
generate one or more skewed Computer-Aided Design (CAD) versions of a semiconductor specimen, wherein each skewed CAD version exhibits a deviation or distortion when compared to an optimal reference design;
apply the one or more skewed CAD versions and physical model outputs to a machine learning (ML) model trained to generate synthetic skewed SEM (Scanning Electron Microscope) images, wherein the ML model is trained using CAD data and real SEM images, along with physical model outputs of a matching physical model, to generate synthetic SEM images that emulate variations reflecting the respective physical model, wherein the matching physical model is indicative of structural and material parameters and tool setting parameters of an SEM tool used for generating the real SEM images;
obtain from the ML model at least one synthetic SEM image of the semiconductor specimen;
apply a metrology tool on the at least one synthetic SEM image to measure parameters in the semiconductor specimen or part thereof, wherein the metrology tool is applied using an EPE inspection recipe for guiding the metrology tool during measurements;
compare true parameter values with measured parameter values determined by the metrology tool; and
validate the EPE inspection recipe if differences between the true parameter values and measured parameter values are within an acceptable range.

11. The computer system of claim 10, wherein in case a difference between the true parameter values and measured parameter values deviates from the acceptable range, the processing circuitry is further configured to perform a recipe optimization procedure comprising:
modifying parameters in the recipe to obtain an updated recipe;
re-applying the metrology tool on the at least one synthetic SEM image using the updated recipe;
comparing true parameter values with measured parameter values determined by the metrology tool;
validating the recipe if one or more differences between the true parameter values and measured parameter values are within an acceptable range; and
repeating the recipe optimization procedure if one or more differences deviate from the acceptable range.

12. The computer system of claim 10, wherein the physical model output includes one or more of: simulated SEM images, signal intensity maps, and electron scattering profiles.

13. The computer system of claim 10, wherein the one or more skewed CAD versions include multiple distinct CAD versions, with each distinct CAD version exhibiting a different deviation or distortion.

14. The computer system of claim 10, wherein the EPE is overlay misalignment, and wherein the deviations or distortions include misalignment between different layers of the semiconductor specimen.

15. The computer system of claim 10, wherein the EPE is line edge roughness, and wherein the deviations or distortions include variations in the edge geometry or surface irregularities of the semiconductor specimen.

16. The computer system of claim 10, wherein the EPE is one of (i) Critical Dimension (CD) deviation, wherein the deviations or distortions include variations in the size of features within a single layer of the semiconductor specimen, or (ii) Critical Dimension Uniformity (CDU) error, wherein the deviations or distortions include inconsistencies in feature sizes across different regions of the semiconductor specimen.

17. The computer system of claim 10, further comprising training the machine learning model using a training data set comprising CAD data of a semiconductor specimen, along with corresponding real SEM images and outputs generated by a respective physical model representing the semiconductor specimen.

18. The computer system of claim 10, wherein the processing circuitry is configured for generating the one or more skewed CAD versions to generate multiple skewed CAD versions, each corresponding to a unique type or degree of EPE variation; wherein the machine learning (ML) model is utilized to generate a respective synthetic skewed SEM image for each skewed CAD design version, and the synthetic skewed SEM images reflect EPE variations exhibited in a respective skewed CAD version; the metrology tool is applied to each synthetic SEM image using the given EPE inspection recipe to thereby perform evaluation of the recipe across a variety of scenarios represented by the respective skewed CAD versions to assess robustness and sensitivity to different EPE variations.

19. A non-transitory computer-readable medium having computer-executable instructions stored thereon, which, when executed by a processor, cause the processor to execute a method for enhancing Edge Placement Errors (EPE) inspection of a semiconductor specimen, the method comprising:
generating one or more skewed Computer-Aided Design (CAD) versions of a semiconductor specimen, wherein each skewed CAD version exhibits a deviation or distortion when compared to an optimal reference design;
applying the one or more skewed CAD versions and physical model outputs to a machine learning (ML) model trained to generate synthetic skewed SEM (Scanning Electron Microscope) images; wherein the ML model is trained using CAD data and real SEM images, along with physical model outputs of a matching physical model, to generate synthetic SEM images that emulate variations reflecting the respective physical model; wherein the matching physical model is indicative of structural and material parameters, and tool setting parameters of an SEM tool used for generating the real SEM images;
obtaining from the ML model at least one of the semiconductor specimens;
applying a metrology tool on the at least one synthetic SEM image to measure parameters in the semiconductor specimen or part thereof, wherein the metrology tool is applied using an EPE inspection recipe for guiding the metrology tool during measurements;
comparing true parameter values with measured parameter values determined by the metrology tool; and
validating the EPE inspection recipe if differences between the true parameter values and measured parameter values are within an acceptable range.
